(19) United States
(12) Patent Application Publication
(10) Pub. No.: US 2025/0301846 A1
(43) Pub. Date: Sep. 25, 2025

(54) DISPLAY PANEL, METHOD FOR MANUFACTURING SAME, AND ELECTRONIC DEVICE COMPRISING SAME

(71) Applicant: Samsung Electronics Co., Ltd., Suwon-si, Gyeonggi-do (KR)

(72) Inventors: Hakyeol KIM, Suwon-si, Gyeonggi-do (KR); Chanhyung YOO, Suwon-si, Gyeonggi-do (KR)

(21) Appl. No.: 18/638,225

(22) Filed: Apr. 17, 2024

Related U.S. Application Data
(63) Continuation of application No. PCT/KR2022/017325, filed on Nov. 7, 2022.

(30) Foreign Application Priority Data
Nov. 8, 2021 (KR) 10-2021-0152630

(51) Int. Cl. H10H 29/851; H01L 25/075; H10H 29/01; H10H 29/85; H10H 29/855

(52) U.S. Cl. CPC H10H 29/8514; H01L 25/0753; H10H 29/0361; H10H 29/8517; H10H 29/8552

(57) ABSTRACT

A display panel is disclosed. The display panel comprises: a substrate divided into a plurality of pixel areas; a plurality of main light-emitting elements and an auxiliary light-emitting element mounted in each of the plurality of pixel areas; and a color conversion layer stacked on the plurality of main light-emitting elements and the auxiliary light-emitting element, wherein the color conversion layer is configured such that light emitted from the auxiliary light-emitting element passes through the color conversion layer and, as a result, has a first color corresponding to a defective first main light-emitting element among the plurality of main light-emitting elements.

### CROSS-REFERENCE TO RELATED APPLICATIONS

This application is continuation of International Application No. PCT/KR2022/017325 designating the United States, filed on Nov. 7, 2022, in the Korean Intellectual Property Receiving Office and claiming priority to Korean Patent Application No. 10-2021-0152630, filed on Nov. 8, 2021, in the Korean Intellectual Property Office, the disclosures of each of which are incorporated by reference herein in their entireties.

### BACKGROUND

### Field

The disclosure relates to a display panel, a method for manufacturing the same, and an electronic device including the same, and for example, to a display panel having an improved structure for replacing a defective main light-emitting element by an auxiliary light-emitting element, and a method for manufacturing the same.

### Description of Related Art

An electronic device including a display panel (e.g.: a display device) adopts a structure wherein lighting is possible by being adjoined on a substrate which is a backplane on which a driving circuit is formed. Recently, research for improving color reproducibility and power consumption by applying light-emitting elements emitting a blue light which is advantageous in light-emitting efficiency and a color conversion layer together on a display device is proceeding.

A color conversion layer is an element including pixels or sub-pixels of a display device, and emits a light converted into one of a red color, a green color, or a blue color by an incident light emitted from a light source of the display device. The display device displays a color image through pixels including the color conversion layer.

Meanwhile, in case it is identified that light-emitting elements are defective after mounting the light-emitting elements on a substrate, there are problems that a rework process of removing the defective light-emitting elements and mounting new light-emitting elements is needed, and a spare mounting space is needed on the substrate, and the entire substrate cannot be used depending on cases.

### SUMMARY

The disclosure relates to a display panel having an improved structure for replacing a defective main light-emitting element by an auxiliary light-emitting element, and a method for manufacturing the same.

A display module according to an example embodiment of the disclosure includes: a substrate divided into a plurality of pixel areas, a plurality of main light-emitting elements and an auxiliary light-emitting element mounted in each of the plurality of pixel areas, and a color conversion layer stacked on the plurality of main light-emitting elements and the auxiliary light-emitting element, wherein the color conversion layer may be configured such that a light emitted from the auxiliary light-emitting element passes through the color conversion layer and has a first color corresponding to a first defective main light-emitting element among the plurality of main light-emitting elements.

A method for manufacturing a display module according to an example embodiment of the disclosure may include: arranging a substrate divided into a plurality of pixel areas, mounting a plurality of main light-emitting elements and an auxiliary light-emitting element in each of the plurality of pixel areas, identifying whether the plurality of main light-emitting elements are defective, and based on a first main light-emitting element among the plurality of main light-emitting elements being defective, stacking a color conversion layer configured such that a light emitted from the auxiliary light-emitting element has a first color corresponding to the first main light-emitting element.

An electronic device according to an example embodiment of the disclosure includes: a display panel including a substrate divided into a plurality of pixel areas, a plurality of main light-emitting elements and an auxiliary light-emitting element mounted in each of the plurality of pixel areas, a color conversion layer stacked on the plurality of main light-emitting elements and the auxiliary light-emitting element, and a driving circuit configured to generate a driving signal of the plurality of main light-emitting elements and the auxiliary light-emitting element, and at least one processor, comprising processing circuitry, individually and/or collectively, configured to: control the driving circuit to generate a driving signal for controlling light emission of the plurality of main light-emitting elements and the auxiliary light-emitting element, wherein the color conversion layer may be configured such that a light emitted from the auxiliary light-emitting element passes through the color conversion layer and has a first color corresponding to a defective main light-emitting element among the plurality of main light-emitting elements.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a block diagram illustrating an example configuration of a display module of an electronic device according to various embodiments;

FIG. 3 is a diagram illustrating a display panel according to various embodiments;

FIG. 4 is a diagram illustrating an enlarged portion IV displayed in FIG. 3, and a pixel structure of a display panel according to various embodiments;

FIG. 5 is a cross-sectional view of a display panel according to various embodiments;

FIGS. 6A and 6B are cross-sectional views of a display panel according to various embodiments;

FIGS. 7A, 7B and 7C are diagrams illustrating a pixel structure of a display panel according to various embodiments;

FIGS. 8A, 8B, 8C and 8D are diagrams illustrating a pentile matrix pixel structure of a display panel according to various embodiments;

FIGS. 9A, 9B and 9C are diagrams illustrating an example in which a plurality of main light-emitting elements are defective in one pixel area according to various embodiments;

FIGS. 10A, 10B and 10C are diagrams illustrating in lights of which colors lights emitted from auxiliary light-emitting elements in normal pixel areas are converted according to various embodiments;

FIG. 11 is a diagram illustrating in lights of which colors lights emitted from auxiliary light-emitting elements in each pixel area are converted in case normal pixel areas and defective pixel areas are mixed according to various embodiments;

FIG. 12 and FIG. 13 include a flowchart and diagrams illustrating an example method for manufacturing a display panel according to various embodiments; and

FIG. 14, FIG. 15 and FIG. 16 include a flowchart and diagrams illustrating an example method for manufacturing a display panel according to various embodiments.

### DETAILED DESCRIPTION

Terms used in the disclosure will be described briefly, and the disclosure will be described in greater detail with reference to the drawings. Meanwhile, in describing the disclosure, detailed explanations regarding related known technologies may be omitted, and overlapping explanation of the same components may be omitted for brevity and clarity.

As terms used in the embodiments of the disclosure, general terms that are currently used widely were selected as far as possible, in consideration of the functions described in the disclosure. However, the terms may vary depending on the intention of those skilled in the art who work in the pertinent field or previous court decisions, or emergence of new technologies. Further, in particular cases, there may be terms may be arbitrarily selected, and in such cases, the meaning of the terms will be described in detail in the relevant descriptions in the disclosure. Accordingly, the terms used in the disclosure should be defined based on the meaning of the terms and the overall content of the disclosure, but not just based on the names of the terms.

In addition, various modifications may be made to the embodiments of the disclosure, and there may be various types of embodiments. Accordingly, various example embodiments will be illustrated in drawings, and the embodiments will be described in detail in the detailed description. However, it should be noted that the various embodiments are not for limiting the scope of the disclosure to a specific embodiment, but they should be interpreted to include all modifications, equivalents, or alternatives of the embodiments included in the ideas and the technical scopes disclosed herein. Meanwhile, in case it is determined that in describing embodiments, detailed explanation of related known technologies may unnecessarily confuse the gist of the disclosure, the detailed explanation may be omitted.

Meanwhile, terms such as “first,” “second,” and the like may be used to describe various components, but the components are not intended to be limited by the terms. The terms are used to distinguish one component from another component. For example, a first component may be called a second component, and a second component may be called a first component in a similar manner, without departing from the scope of the disclosure.

Also, singular expressions include plural expressions, unless used differently in the context. Further, in the disclosure, terms such as “include” and “consist of” should be construed as designating that there are such characteristics, numbers, steps, operations, elements, components, or a combination thereof described in the disclosure, but not as excluding in advance the existence or possibility of adding one or more of other characteristics, numbers, steps, operations, elements, components, or a combination thereof.

In addition, in the disclosure, “a module” or “a part” performs at least one function or operation, and may be implemented as hardware or software, or a combination of hardware or software. Also, a plurality of “modules” or a plurality of “parts” may be integrated into at least one module and implemented as at least one processor, except “a module” or a part” that needs to be implemented as specific hardware.

Hereinafter, various example embodiments of the disclosure will be described in greater detail with reference to the accompanying drawings. However, the disclosure may be implemented in several different forms, and are not limited to the embodiments described herein. Also, in the drawings, parts that are not related to explanation may be omitted, for explaining the disclosure clearly, and throughout the disclosure, similar parts are designated by similar reference numerals.

Further, while the embodiments of the disclosure will be described in detail with reference to the following accompanying drawings and the content described in the accompanying drawings, it is not intended that the disclosure is restricted or limited by the embodiments.

Hereinafter, a display module and an electronic device including the same according to various example embodiments of the disclosure will be described in greater detail with reference to the drawings.

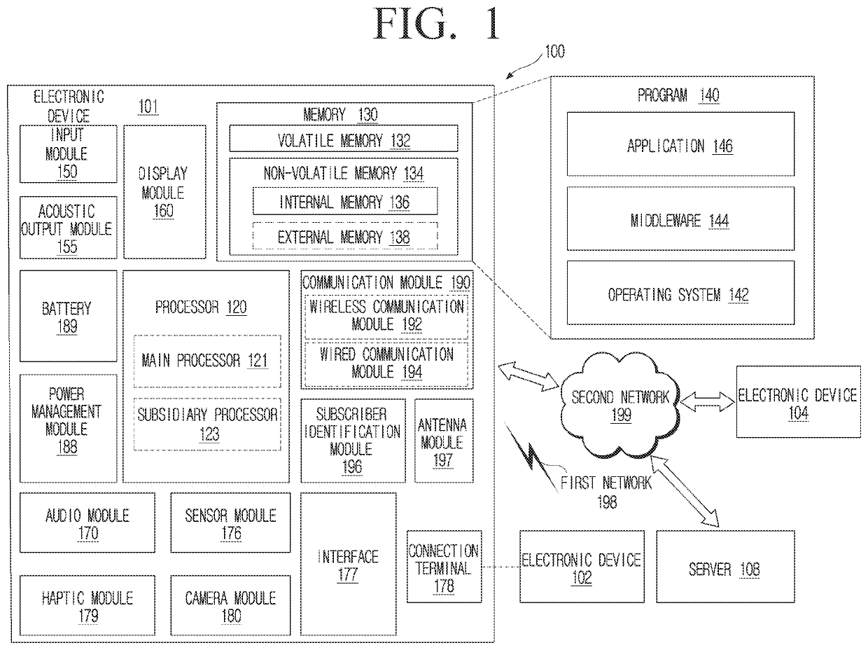

FIG. 1 is a block diagram illustrating an example electronic device in a network environment according to various embodiments.

FIG. 1 is a block diagram of an electronic device 101 in a network environment 100 according to various embodiments. For reference, hereinafter, a machine according to various embodiments of the disclosure will be generally referred to as ‘an electronic device,’ for the convenience of explanation, but the machine according to the various embodiments may be an electronic device, a wireless communication device, a display device, or a portable communication device.

Referring to FIG. 1, in the network environment 100, the electronic device 101 may communicate with an electronic device 102 through a first network 198 (e.g.: a near field wireless communication network), or communicate with at least one of an electronic device 104 or a server 108 through a second network 199 (e.g.: a long distance wireless communication network). According to an embodiment, the electronic device 101 may communicate with the electronic device 104 through the server 108. Also, according to an embodiment, the electronic device 101 may include a processor 120, a memory 130, an input module 150, an acoustic output module 155, a display module 160, an audio module 170, a sensor module 176, an interface 177, a connection terminal 178, a haptic module 179, a camera module 180, a power management module 188, a battery 189, a communication module 190, a subscriber identification module (SIM) 196, or an antenna module 197. In various embodiments, in the electronic device 101, at least one (e.g.: the connection terminal 178) of these components may be omitted, or one or more other components may be added. Also, in various embodiments, some (e.g.: the sensor module 176, the camera module 180, or the antenna module 197) of these components may be integrated as one component (e.g.: the display module 160).

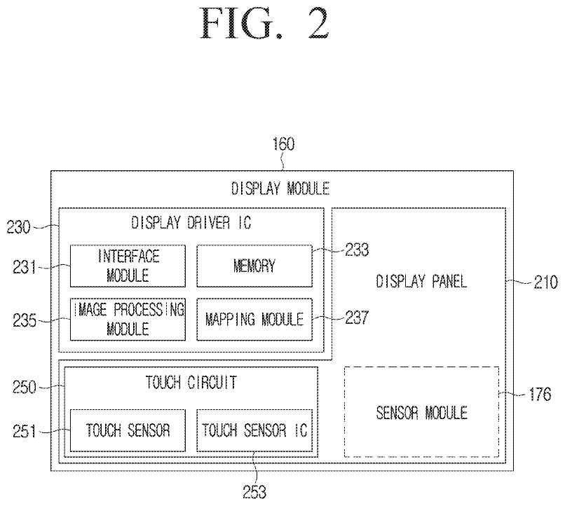

According to an embodiment, the electronic device 101 may display various images. Here, an image may include a still image and a moving image, and the electronic device 101 may display various images such as a broadcasting content, a multimedia content, etc. Also, the electronic device 101 may display a user interface (UI) and an icon. For example, the display module 160 (refer to FIG. 1) may include a display driver IC 230 (refer to FIG. 2), and display an image based on an image signal received from the processor 120 (refer to FIG. 1). As an example, the display driver IC 230 may generate a driving signal of a plurality of sub-pixels based on an image signal received from the processor 120, and display an image by controlling light emission of the plurality of sub-pixels based on the driving signal.

According to an embodiment, the processor 120 may control the overall operations of the electronic device 101. The processor 120 may include one or a plurality of processors. For example, the processor 120 may perform the operations of the electronic device 101 according to various embodiments of the disclosure by executing at least one instruction stored in the memory.

According to an embodiment, the processor 120 may be implemented as a digital signal processor (DSP) processing digital image signals, a microprocessor, a graphics processing unit (GPU), an artificial intelligence (AI) processor, a neural processing unit (NPU), and a time controller (TCON). However, the disclosure is not limited thereto, and the processor 120 may include one or more of a central processing unit (CPU), a micro controller unit (MCU), a micro processing unit (MPU), a controller, an application processor (AP) or a communication processor (CP), and an ARM processor, or may be defined by the terms. Also, the processor 120 may be implemented as a system on chip (SoC) having a processing algorithm stored therein or large scale integration (LSI), or implemented in the form of an application specific integrated circuit (ASIC) or a field programmable gate array (FPGA).

According to an embodiment, the processor 120 may control hardware or software components connected to the processor 120 by driving an operating system or an application program, and perform various kinds of data processing and operations. Also, the processor 120 may load an instruction or data received from at least one of the other components on a volatile memory and process it, and store various kinds of data in a non-volatile memory.

According to an embodiment, the processor 120 may control at least one other component (e.g. a hardware or software component) of the electronic device 101 connected to the processor 120 by executing software (e.g.: a program 140), and perform various kinds of data processing or operations. Also, according to an embodiment, as at least a part of data processing or an operation, the processor 120 may load an instruction or data received from another component (e.g.: the sensor module 176 or the communication module 190) on a volatile memory 132, process the instruction or data stored in the volatile memory 132, and store the result data in a non-volatile memory 134. In addition, according to an embodiment of the disclosure, the processor 120 may include a main processor 121 (e.g.: a central processing unit or an application processor), or a subsidiary processor 123 that can be operated independently therefrom or together (e.g.: a graphics processing device, a neural network processing device (a neural processing unit (NPU)), an image signal processor, a sensor hub processor, or a communication processor). For example, in case the electronic device 101 includes a main processor 121 and a subsidiary processor 123, the subsidiary processor 123 may be set to use lower power than the main processor 121, or to be specified for a designated function. Also, the subsidiary processor 123 may be implemented separately from the main processor 121, or as a part thereof. In other words, the processor 120 according to an embodiment of the disclosure may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

According to an embodiment, the subsidiary processor 123 may control at least some of the functions or states related to at least one component (e.g.: the display module 160, the sensor module 176, or the communication module 190) among the components of the electronic device 101 in place of the main processor 121 while the main processor 121 is in an inactive (e.g.: sleep) state, or together with the main processor 121 while the main processor 121 is in an active (e.g.: application execution) state. Also, according to an embodiment, the subsidiary processor 123 (e.g.: the image signal processor or the communication processor) may be implemented as a part of another component (e.g.: the camera module 180 or the communication module 190) that is functionally related. In addition, according to an embodiment, the subsidiary processor 123 (e.g.: a neural network processing device) may include a hardware structure specified for processing of an artificial intelligence model. An artificial intelligence model may be generated through machine learning. Such learning may be performed, for example, in the electronic device 101 itself wherein the artificial intelligence model is performed, or performed through a separate server (e.g.: the server 108). Learning algorithms may include, for example, supervised learning, unsupervised learning, semi-supervised learning, or reinforcement learning, but the learning algorithms are not limited to the aforementioned examples. An artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), and deep Q-networks, or a combination of two or more of the above, but is not limited to the aforementioned examples. An artificial intelligence model may include a software structure additionally or alternatively, other than a hardware structure.

According to an embodiment, the memory 130 may store various kinds of data used by at least one component (e.g.: the processor 120 or the sensor module 176) of the electronic device 101. The data may include, for example, software (e.g.: the program 140), and input data or output data regarding an instruction related to this. The memory 130 may include the volatile memory 132 or the non-volatile memory 134.

According to an embodiment, the processor 120 may be stored as software in the memory 130, and may include, for example, an operating system 142, middleware 144, or an application 146.

According to an embodiment, the input module 150 may receive an instruction or data to be used for a component (e.g.: the processor 120) of the electronic device 101 from the outside (e.g.: a user) of the electronic device 101. The input module 150 may include, for example, a microphone, a mouse, a keyboard, a key (e.g.: a button), or a digital pen (e.g.: a stylus pen).

According to an embodiment, the acoustic output module 155 may output an acoustic signal to the outside of the electronic device 101. The acoustic output module 155 may include, for example, a speaker or a receiver. The speaker may be used for general uses such as reproduction of multimedia or reproduction of recording. The receiver may be used for receiving an incoming call. According to an embodiment, the receiver may be implemented separately from the speaker, or as a part thereof.

According to an embodiment, the display module 160 may visually provide information to the outside (e.g.: a user) of the electronic device 101. The display module 160 may include, for example, a display, a hologram device, or a projector, and a control circuit for controlling the device. Also, according to an embodiment, the display module 160 may include a touch sensor 251 set to detect a touch, and include a pressure sensor set to measure the strength of a force generated by a touch. Meanwhile, the detailed configuration of the display module 160 will be described in detail with reference to FIG. 2.

According to an embodiment, the audio module 170 may convert a sound into an electric signal, or convert an electric signal into a sound, on the contrary. Also, according to an embodiment, the audio module 170 may acquire a sound through the input module 150, or output a sound through the acoustic output module 155, or an external electronic device (e.g.: the electronic device 102) (e.g.: a speaker or a headphone) connected with the electronic device 101 directly or wirelessly.

According to an embodiment, the sensor module 176 may detect an operation state (e.g.: the power or the temperature) of the electronic device 101, or an external environment state (e.g.: a user state), and generate an electric signal or a data value corresponding to the detected state. Also, according to an embodiment, the sensor module 176 may include, for example, a gesture sensor, a gyro sensor, an air barometric sensor, a magnetic sensor, an acceleration sensor, a grip sensor, a proximity sensor, a color sensor, an infrared (IR) sensor, a bio sensor, a temperature sensor, a humidity sensor, or an illumination sensor.

According to an embodiment, the interface 177 may support one or more designated protocols that can be used for the electronic device 101 to be connected with an external electronic device (e.g.: the electronic device 102) directly or wirelessly. Also, according to an embodiment, the interface 177 may include, for example, a high definition multimedia interface (HDMI), a universal serial bus (USB) interface, an SD card interface, or an audio interface.

According to an embodiment, the connection terminal 178 may include a connector through which the electronic device 101 can be physically connected with an external electronic device (e.g.: the electronic device 102). Also, according to an embodiment, the connection terminal 178 may include, for example, an HDMI connector, a USB connector, an SD card connector, or an audio connector (e.g.: a headphone connector).

According to an embodiment, the haptic module 179 may convert an electric signal into mechanical stimulus (e.g.: vibration or movement) or electric stimulus that a user can recognize through tactile or kinetic sense. Also, according to an embodiment, the haptic module 179 may include, for example, a motor, a piezoelectric element, or an electric stimulus device.

According to an embodiment, the camera module 180 may photograph a still image and a moving image. Also, according to an embodiment, the camera module 180 may include one or more lenses, image sensors, image signal processors, or flashes.

According to an embodiment, the power management module 188 may manage power provided to the electronic device 101. Also, according to an embodiment, the power management module 188 may be implemented as, for example, at least a part of a power management integrated circuit (PMIC).

According to an embodiment, the battery 189 may provide power to at least one component of the electronic device 101. Also, according to an embodiment, the battery 189 may include, for example, a primary battery that cannot be recharged, a secondary battery that can be recharged, or a fuel cell.

According to an embodiment, the communication module 190 may establish a direct (e.g.: wired) communication channel or a wireless communication channel between the electronic device 101 and an external electronic device (e.g.: the electronic device 102, the electronic device 104, or the server 108), and support performance of communication through the established communication channel. The communication module 190 may be operated independently from the processor 120 (e.g.: an application processor), and include one or more communication processors that support direct (e.g.: wired) communication or wireless communication. Also, according to an embodiment, the communication module 190 may include a wireless communication module 192 (e.g.: a cellular communication module, a near field wireless communication module, or a global navigation satellite system (GNSS) communication module) or a wired communication module 194 (e.g.: a local area network (LAN) communication module, or a power line communication module). A corresponding communication module among these communication modules may communicate with the external electronic device 104 through a first network 198 (e.g.: a near field communication network such as Bluetooth, wireless fidelity (WiFi) direct, or infrared data association (IrDA)) or a second network 199 (e.g.: a long distance communication network such as a legacy cellular network, a 5G network, a next generation communication network, the Internet, or a computer network (e.g.: a LAN or a WAN)). These several kinds of communication modules may be integrated as one component (e.g.: a single chip), or implemented as a plurality of components (e.g.: a plurality of chips) separate from one another. The wireless communication module 192 may identify or authenticate the electronic device 101 in a communication network such as the first network 198 or the second network 199 using subscriber information (e.g.: an international mobile subscriber identity (IMSI)) stored in the subscriber identification module 196.

According to an embodiment, the wireless communication module 192 may support the 5G network after the 4G network and a next generation communication technology, e.g., a new radio (NR) access technology. The NR access technology may support high speed transmission of high capacity data (enhanced mobile broadband (eMBB)), minimalization of terminal power and access of a plurality of terminals (massive machine type communications (mMTC)), or high reliability and low latency (ultra-reliable and low-latency communications (URLLC)). The wireless communication module 192 may support, for example, a high frequency bandwidth (e.g.: an mmWave bandwidth) for achievement of a high data transmission rate. The wireless communication module 192 may support various technologies for securing performance in a high frequency bandwidth, e.g., technologies such as beamforming, massive multiple-input and multiple-output (MIMO), full dimensional MIMO (FD-MIMO), an array antenna, analog beam-forming, or a large scale antenna. The wireless communication module 192 may support various requirements prescribed in the electronic device 101, an external electronic device (e.g.: the electronic device 104), or a network system (e.g.: the second network 199). According to an embodiment, the wireless communication module 192 may support a peak data rate (e.g.: 20 Gbps or higher) for realizing eMBB, a loss coverage (e.g.: 164 dB or lower) for realizing mMTC, or U-plane latency (e.g.: 0.5 ms or lower of each of a downlink (DL) and an uplink (UL), or 1 ms or lower of a round trip) for realizing URLLC.

According to an embodiment, the antenna module 197 may transmit a signal or power to the outside (e.g.: an external electronic device) or receive them from the outside. Also, according to an embodiment, the antenna module 197 may include a plurality of antennas (e.g.: array antennas), and at least one antenna appropriate for a communication method used in a communication network such as the first network 198 or the second network 199 may be selected from the plurality of antennas by, for example, the communication module 190.

According to an embodiment, the antenna module 197 may include a plurality of antennas (e.g.: array antennas), and according to an embodiment, the antenna module 197 may include an antenna including an emitter including a conductor or a conductive pattern formed on a substrate (e.g.: a PCB).

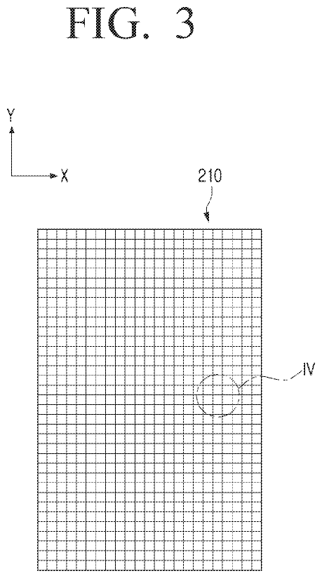

According to various embodiments, the antenna module 197 may form an mmWave antenna module. According to an embodiment, an mmWave antenna module may include a printed circuit board, an RFIC which is arranged on the first surface (e.g.: the lower surface) of the printed circuit board or in an adjacent location thereto and which can support a designated high frequency bandwidth (e.g.: an mmWave bandwidth), and a plurality of antennas (e.g.: array antennas) which are arranged on the second surface (e.g.: the upper surface or a side surface) of the printed circuit board or in an adjacent location thereto and which can transmit or receive a signal of the designated high frequency bandwidth. The detailed configuration of the antennal module 197 according to the various embodiments of the disclosure will be described in detail with reference to FIG. 3 and the drawings after that.

A signal or power may be transmitted or received between the communication module 190 and an external electronic device through at least one antenna. According to various embodiments, another component (e.g.: a radio frequency integrated circuit (RFIC)) may additionally be formed as a part of the antenna module 197 other than an emitter.

At least some of the components as described above may be connected with one another through a communication method among ambient devices (e.g.: a bus, a general purpose input and output (GPIO), a serial peripheral interface (SPI), or a mobile industry processor interface (MIPI)), and exchange signals (e.g.: instructions or data) with one another.

Instructions or data may be transmitted or received between the electronic device 101 and the external electronic device 104 through the server 108 connected to the second network 199. Each of the external electronic devices 102 or 104 may be a device that is of a type identical to or different from the electronic device 101. According to an embodiment, all or some of the operations executed in the electronic device 101 may be executed in one or more external electronic devices among the external electronic devices 102, 104, or 108. For example, in case the electronic device 101 has to perform a certain function or service automatically, or in response to a request from a user or another electronic device, the electronic device 101 may request the one or more external electronic devices to perform at least a part of the function or the service, instead of executing the function or the service by itself or in addition to it. The one or more external electronic devices that received the request may execute at least a part of the requested function or service, or an additional function or service related to the request, and transmit the result of the execution to the electronic device 101. The electronic device 101 may process the result as it is or additionally, and provide it as at least a part of a response to the request. For this, for example, a cloud computing technology, a distributed computing technology, a mobile edge computing (MEC) technology, or a client-server computing technology may be used. The electronic device 101 may, for example, provide an ultra-low latency service using distributed computing or mobile edge computing. According to an embodiment, the external electronic device 104 may include an Internet of Things (IoT) device. The server 108 may be an intelligent server using machine learning/or a neural network. According to an embodiment, the external electronic device 104 or the server 108 may be included in the second network 199. The electronic device 101 may be applied to intelligent services (e.g.: a smart home, a smart city, a smart car, or health care) based on 5G communication technologies and IoT-related technologies.

FIG. 2 is a block diagram illustrating an example configuration of a display module of an electronic device according to various embodiments.

Referring to FIG. 2, the display module 160 may include a display panel 210, and a display driver IC (DDI) 230 for controlling the display panel 210.

The display driver IC 230 may include an interface module (e.g., including interface circuitry) 231, a memory 233 (e.g.: a buffer memory), an image processing module (e.g., including image processing circuitry) 235, and/or a mapping module (e.g., including circuitry) 237. The display driver IC 230 may receive, for example, image information including image data, or an image control signal corresponding to an instruction for controlling the image data from another component of the electronic device 101 through the interface module 231. For example, according to an embodiment, the image information may be received from the processor 120 (e.g.: the main processor 121 (e.g.: an application processor) or the subsidiary processor 123 (e.g.: a graphics processing device) that is independently operated from the function of the main processor 121.

The display driver IC 230 may communicate with a touch circuit 250 or the sensor module 176 through the interface module 231. Also, the display driver IC 230 may store at least a part of the received image information in the memory 233 in, for example, frame units. The image processing module 235 may, for example, perform pre-processing or post-processing (e.g.: adjustment of the resolution, the brightness, or the size) for at least a part of the image data at least based on the characteristics of the image data or the characteristics of the display panel 210. The mapping module 237 may generate a voltage value or a current value corresponding to the pre-processed or post-processed image data through the image processing module 235. According to an embodiment, generation of a voltage value or a current value may be performed, for example, based at least partially on the attributes of the pixels of the display panel 210 (e.g.: the arrangement of the pixels (an RGP stripe or a pentile structure), or the sizes of each sub-pixel). At least some pixels of the display panel 210 may be driven, for example, based at least partially on the voltage value or the current value, and accordingly, visual information (e.g.: a text, an image, or an icon) corresponding to the image data may be displayed through the display panel 210.

According to an embodiment, the display driver IC 230 may transmit a driving signal (e.g.: a driver driving signal, a gate driving signal, etc.) to the display based on the image information received from the processor 120. The display driver IC 230 may operate by itself while the processor 120 is in a sleep mode, and display various kinds of information (e.g.: the current time, the state of reception of message, etc.).

According to an embodiment, the display module 160 may further include a touch circuit 250. The touch circuit 250 may include a touch sensor 251 and a touch sensor IC 253 for controlling the touch sensor 251. The touch sensor IC 253 may, for example, control the touch sensor 251 for detecting a touch input or a hovering input for a designated location of the display panel 210. For example, the touch sensor IC 253 may detect a touch input or a hovering input by measuring the change of a signal (e.g.: a voltage, a light amount, a resistance, or a charge amount) for a designated location of the display panel 210. The touch sensor IC 253 may provide information about the detected touch input or hovering input (e.g.: the location, the area, the pressure, or the time) to the processor 120. According to an embodiment, at least a part of the touch circuit 250 (e.g.: the touch sensor IC 253) may be included as a part of the display driver IC 230 or the display panel 210, or a part of another component arranged on the outside of the display module 160 (e.g.: the subsidiary processor 123).

According to an embodiment, the display module 160 may further include at least one sensor (e.g.: a fingerprint sensor, an iris sensor, a pressure sensor, or an illumination sensor) of the sensor module 176, or a control circuit for it. In this case, the at least one sensor or the control circuit for it may be embedded in a part of the display module 160 (e.g.: the display panel 210 or the display driver IC 230), or a part of the touch circuit 250. For example, in case the sensor module 176 embedded in the display module 160 includes a bio sensor (e.g.: a fingerprint sensor), the bio sensor may acquire bio information (e.g.: a fingerprint image) associated with a touch input through a partial area of the display panel 210. As another example, in case the sensor module 176 embedded in the display module 160 includes a pressure sensor, the pressure sensor may acquire pressure information associated with a touch input through a partial area or the entire area of the display panel 210. According to an embodiment, the touch sensor 251 or the sensor module 176 may be arranged between the pixels of the pixel layer of the display panel 210, or on or under the pixel layer.

According to an embodiment, the processor (e.g.: the processor 120 in FIG. 1) may transmit various kinds of information to each module at the processor 120, and may then be converted into an inactivated state. The processor 120 may be in the inactivated state in an always on display (AOD) mode. The processor 120 may maintain the inactivated state in the AOD mode, and may be activated in a case of transmitting image information and/or control information to the display driver IC 230, the touch sensor IC 253, and a pressure sensor IC (not shown) and transmit information, and may then be converted into the inactivated state again.

According to an embodiment, the display driver IC 230 may transmit a driving signal (e.g.: a driver driving signal, a gate driving signal, etc.) to the display based on the image information received from the processor 120. The display driver IC 230 may operate by itself while the processor 120 is in a sleep mode, and display various kinds of information (e.g.: the current time, the state of reception of message, etc.).

The electronic device according to the various embodiments disclosed in the disclosure may be devices in various forms. The electronic device may include, for example, a portable communication device (e.g.: a smartphone), a computer device, a portable multimedia device, a portable medical device, a camera, a wearable device, a home appliance, or the like. However, the electronic device according to embodiments of the disclosure is not limited to the aforementioned devices.

The various embodiments of the disclosure and the terms used in the embodiments are not intended to limit the technical characteristics described in the disclosure to specific embodiments, but they should be interpreted to include various modifications, equivalents, or alternatives of the embodiments. Meanwhile, with respect to the detailed description of the drawings, similar or related components may be designated by similar reference numerals. Also, a singular form of a noun corresponding to an item may include one or a plurality of the item, unless used differently in the context. Also, in the disclosure, each of the phrases “A or B,” “at least one of A and B,” “at least one of A or B,” “A, B, or C,” “at least one of A, B, and C,” and “at least one of A, B, or C” may include any one of the items listed together with the corresponding phrase among the phrases, or all possible combinations thereof. In addition, terms such as “first,” “second,” and the like may be used just to distinguish a component from another component, and are not intended to limit a component in another aspect (e.g.: importance or order). Meanwhile, in case it is mentioned that a component (e.g.: a first component) is “coupled” or “connected” with another component (e.g.: a second component) together with terms such as “functionally” and “communicatively” or without such terms, the component may be connected with the another component directly (e.g.: in a wired manner), wirelessly, or through a third component.

The term “module” used in the various embodiments of the disclosure may include a unit implemented as hardware, software, or firmware, or any combination thereof, and may be interchangeably used with, for example, terms such as a logic, a logical block, a component, or a circuit. In addition, a module may be a component included as an integrated body or a minimum unit or a part of the component performing one or more functions. For example, according to an embodiment, a module may be implemented in the form of an application-specific integrated circuit (ASIC).

The various embodiments of the disclosure may be implemented as software (e.g.: the program 140) including at least one instruction stored in a storage medium (e.g.: an internal memory 136 or an external memory 138) that is readable by machines (e.g.: the electronic device 101). For example, a machine (e.g.: the processor (e.g.: the processor 120) of the electronic device 101) may call at least one instruction among one or more instructions stored in a storage medium, and execute the instruction. This enables a device to be operated to perform at least one function according to the at least instruction called. The one or more instructions may include a code that is generated by a compiler or a code that can be executed by an interpreter. A storage medium that is readable by machines may be stored in the form of a non-transitory storage medium. Here, the ‘non-transitory’ storage medium is a tangible device, and may not include a signal (e.g.: an electromagnetic wave), and the term does not indicate whether data is stored in the storage medium semi-permanently or temporarily.

According to an embodiment, the method according to the various embodiments disclosed in the disclosure may be provided while being included in a computer program product. A computer program product refers to a product, and it can be traded between a seller and a buyer. A computer program product can be distributed in the form of a storage medium that is readable by machines (e.g.: a compact disc read only memory (CD-ROM)), or may be distributed directly between two user devices (e.g.: smartphones), and distributed on-line (e.g.: download or upload) through an application store (e.g.: Play Store™). In the case of on-line distribution, at least a portion of a computer program product may be stored in a storage medium such as the server of the manufacturer, the server of the application store, and the memory of the relay server at least temporarily, or may be generated temporarily.

According to the various embodiments, each of the aforementioned components (e.g.: a module or a program) may include a singular object or a plurality of objects, and some of the plurality of objects may be separately arranged in another component. Also, according to the various embodiments, among the aforementioned corresponding components, at least one component or operation may be omitted, or one or more other components or operations may be added. Alternatively or additionally, a plurality of components (e.g.: a module or a program) may be integrated as an object. In this case, the integrated components may perform one or more functions of each of the plurality of components identically or in a similar manner to how they were performed by the corresponding components among the plurality of components before integration. Further, according to the various embodiments, operations performed by a module, a program, or other components may be executed sequentially, in parallel, repetitively, or heuristically. Or, at least some of the operations may be executed in a different order or omitted, or other operations may be added.

The electronic device 101 according to an embodiment of the disclosure may include a single unit, and may be applied on wearable devices, portable devices, handheld devices, and electronic products or electronic components which need various kinds of displays such as a mobile device or a wireless communication device. Also, the electronic device 101 according to an embodiment may be implemented as a TV. Alternatively, the electronic device 101 can be applied to any device equipped with a display function such as a video wall, a large format display (LFD), digital signage, a digital information display (DID), a projector display, etc. without limitation.

Also, in the electronic device 101 according to an embodiment of the disclosure, the plurality of display modules 160 may be implemented as a matrix type, and thus the electronic device 101 may be applied to various display devices such as monitors for personal computers (PCs), high resolution TVs and signage (or, digital signage), and electronic displays through a plurality of assembly arrangements.

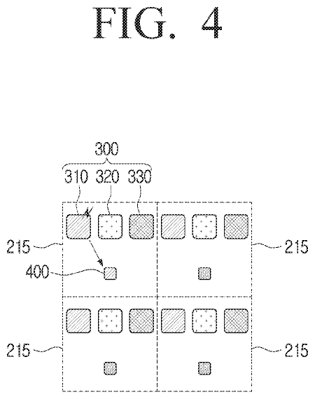

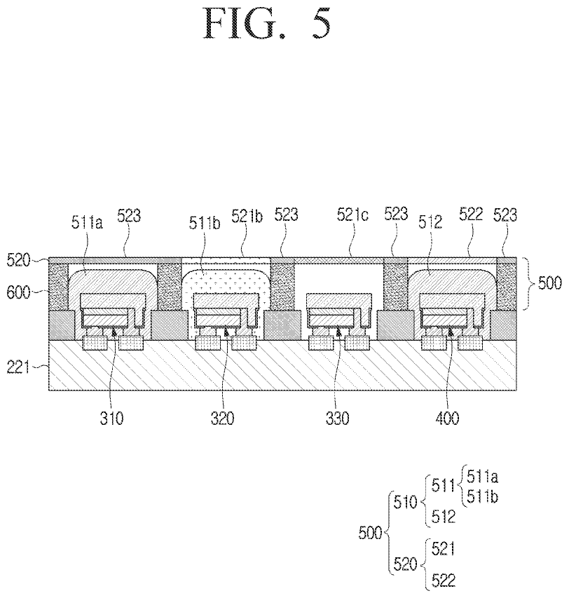

FIG. 3 is a diagram illustrating an example display panel according to various embodiments. FIG. 4 is a diagram illustrating an enlarged IV portion of FIG. 3, illustrating an example pixel structure of a display panel according to various embodiments. FIG. 5 is a cross-sectional view of a display panel according to various embodiments.

Referring to FIGS. 3, 5 and 5, the display panel 210 according to an embodiment of the disclosure may include a substrate 221, main light-emitting elements 300, an auxiliary light-emitting element 400, a color conversion layer 500, and a barrier 600.

According to an embodiment, the substrate 221 may be divided into a plurality of pixel areas 215. The plurality of main light-emitting elements 300 and the auxiliary light-emitting element 400 may respectively be mounted on the plurality of pixel areas 215. The plurality of main light-emitting elements 300 and the auxiliary light-emitting element 400 may be blue micro light-emitting diodes (LEDs) emitting a blue light.

According to an embodiment, the plurality of main light-emitting elements 300 may include a first main light-emitting element 310, a second main light-emitting element 320, and a third main light-emitting element 330. Each of the first to third main light-emitting elements 310, 320, 330 may correspond to one color among a red color, a green color, and a blue color, and the light emitted by each of them may be converted into a light of a corresponding color of each of them by the color conversion layer 500.

For example, the first main light-emitting element 310 may correspond to the red color, and a blue light emitted from the first light-emitting element 310 may be converted into a light of the red color as it passes through the color conversion layer 500. The second main light-emitting element 320 may correspond to the green color, and a blue light emitted from the second main light-emitting element 320 may be converted into a light of the green color as it passes through the color conversion layer 500.

According to an embodiment, the color conversion layer 500 may be stacked on the plurality of main light-emitting elements 300 and the auxiliary light-emitting element 400. The color conversion layer 500 may be formed such that a light emitted from the auxiliary light-emitting element 400 passes through the color conversion layer 500 and has a first color corresponding to the first main light-emitting element 310 which is defective among the plurality of main light-emitting elements 300.

For example, the color of the light emitted from the auxiliary light-emitting element 400 after passing through the color conversion layer 500 may vary depending on which main light-emitting element 300 among the plurality of main light-emitting elements 300 is defective.

For example, in case the first main light-emitting element corresponds to the red color, the color conversion layer 500 may be formed such that the light emitted from the auxiliary light-emitting element 400 passes through the color conversion layer 500 and has the red color.

Accordingly, in case the main light-emitting elements 300 in a specific pixel area 215 are defective, the auxiliary light-emitting element 400 passes through the color conversion layer 500 and is converted into a light of a color corresponding to the defective main light-emitting elements 300, and thus the pixel may be driven normally.

According to an embodiment, in case defective light-emitting elements were found in a manufacturing process of a display panel, the corresponding pixel may be repaired normally using ay auxiliary light-emitting element 400 that was already mounted, without having to remove the defective light-emitting elements and mounting new light-emitting elements on a substrate.

According to an embodiment, the color conversion layer 500 may include a color conversion medium 510 and a color filter layer 520. The color conversion medium 510 may include a main color conversion medium 511 stacked on the main light-emitting elements 300 and an auxiliary color conversion medium 512 stacked on the auxiliary light-emitting element 400.

According to an embodiment, the main color conversion medium 511 may include a first main color conversion medium 511a and a second main color conversion medium 511b.

The first main color conversion medium 511a may include a red phosphor that is stacked on the first main light-emitting element 310, and is excited by a light emitted from the first main light-emitting element 310 and emits a light of a red wavelength band.

The second main color conversion medium 511b may include a green phosphor that is stacked on the second main light-emitting element 320, and is excited by a light emitted from the second main light-emitting element 320 and emits a light of a green wavelength band.

According to an embodiment, the auxiliary color conversion medium 512 may convert a light emitted from the auxiliary light-emitting element 400 into a light of the first color corresponding to the first main light-emitting element 310 which is defective among the plurality of main light-emitting elements 300.

For example, in case the first main light-emitting element 310 which is defective corresponds to the red color, the auxiliary color conversion medium 512 may convert a light emitted from the auxiliary light-emitting element 400 into a light of the red color.

Accordingly, in case the main light-emitting elements 300 in the specific pixel area 215 are defective, the auxiliary light-emitting element 400 passes through the auxiliary color conversion medium 512 and is converted into a light of a color corresponding to the defective main light-emitting elements 300, and thus the pixel may be driven normally.

The color filter layer 520 may be arranged on the upper side of the plurality of main light-emitting elements 300 and the auxiliary light-emitting element 400, and include color filters 521, 522 of different colors and a black matrix 523. For example, the color filter layer 520 may include, for example, the main color filter 521 respectively arranged on the upper side of the plurality of main light-emitting elements 300, the auxiliary color filter 522 arranged on the upper side of the auxiliary light-emitting element 400, and the black matrix 523 arranged to surround the plurality of color filters.

According to an embodiment, the main color filter 521 may include a second main color filter 521b and a third main color filter 521c. The second main color filter 521b may be arranged on the upper side of the second main light-emitting element 320, and the third main color filter 521c may be arranged on the upper side of the third main light-emitting element 330.

The second main color filter 521b may be a filter including color pixels expressing a second color (e.g.: green). For example, the second main color filter 521b may be a filter that includes a polarizing member, and selectively makes a light of a wavelength corresponding to the second color pass through, and absorbs a light of another wavelength.

Likewise, the third main color filter 521c may be a filter including color pixels expressing a third color (e.g.: blue). For example, the third main color filter 521c may be a filter that includes a polarizing member, and selectively makes a light of a wavelength corresponding to the third color pass through, and absorbs a light of another wavelength.

According to an embodiment, the auxiliary color filter 522 may be stacked on the auxiliary color conversion medium 512, and selectively make only a light of the first color (e.g.: red) corresponding to the first main light-emitting element 310 which is defective among the plurality of main light-emitting elements 300 pass through. For example, in case the first main light-emitting element 310 which is defective corresponds to the red color, the auxiliary color filter 522 may selectively make only a light of the red color pass through. Accordingly, color reproducibility in sub-pixels corresponding to the auxiliary light-emitting element 400 can be improved.

According to an embodiment, on the upper side of the first main light-emitting element 310 which is defective among the plurality of main light-emitting elements 300, the black matrix 523 may be arranged. Accordingly, in case the first main light-emitting element 310 which is defective emits a light unintentionally, the light may be absorbed by the black matrix 523.

According to an embodiment, the barrier 600 may be arranged on the substrate 221 and divide the plurality of pixel areas 215 and the sub-pixel areas. The barrier 600 may be formed in a lattice arrangement and form a plurality of cells, and accommodate the light-emitting elements 310, 320, 330, 400 and the color conversion media 511a, 511b, 512 in its inside.

The barrier 600 may surround each of the plurality of light-emitting elements 310, 320, 330, 400, and output lights of colors corresponding to each sub-pixel area through the color conversion media 511a, 511b, 512 accommodated in its inside, and the lights output from different sub-pixel areas may gather and implement one pixel area 215.

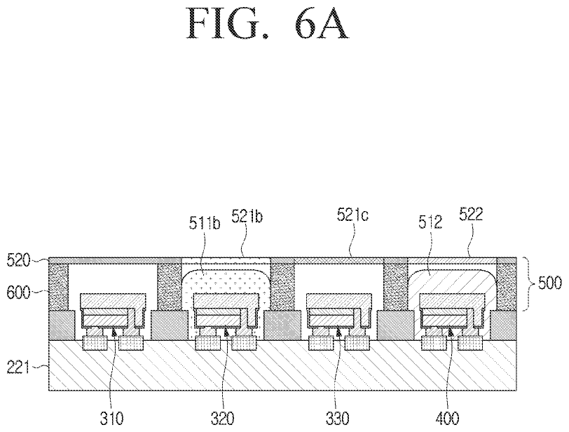

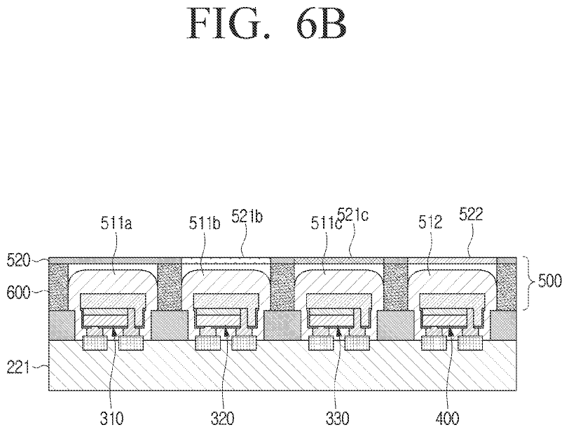

FIGS. 6A and 6B are cross-sectional views of a display panel according to various embodiments.

According to FIG. 6A, the auxiliary color conversion medium 512 may convert a light emitted from the auxiliary light-emitting element 400 into a light of a white color, and the auxiliary color filter 522 may selectively make only a light of the first color corresponding to the first main light-emitting element 310 which is defective among the plurality of main light-emitting elements 300 pass through.

According to an embodiment, the auxiliary color conversion medium 512 may include a red phosphor and a green phosphor that are stacked on the auxiliary light-emitting element 400, and are excited by a light emitted from the auxiliary light-emitting element 400, and emit a light of a red wavelength band, and emit a light of a green wavelength band. Accordingly, a light of the blue color emitted from the auxiliary light-emitting element 400 may be converted into a light of the white color as it passes through the auxiliary color conversion medium 512.

For example, before stacking the color conversion media 511b, 512 on the light-emitting elements 310, 320, 330, 400, it may be found out that the first main light-emitting element 310 is defective. In this case, on the upper side of the first main light-emitting element 310, a color conversion medium may not be stacked, but the black matrix 523 may be arranged. Also, on the upper side of the auxiliary light-emitting element 400, the auxiliary color conversion medium 512 that converts a light emitted from the auxiliary light-emitting element 400 into a light of the white color may be stacked, and the auxiliary color filter 522 that selectively makes only a light of the first color corresponding to the first main light-emitting element 310 pass through may be arranged. For example, in case the first main light-emitting element 310 which is defective corresponds to the red color, a light of the blue color emitted from the auxiliary light-emitting element 400 may be converted into a white light by the auxiliary color conversion medium 512, and afterwards, the light may be converted into a light of the red color by the auxiliary color filter 522.

Here, the main color conversion medium 511 may also convert a light emitted from the main light-emitting elements 300 into a light of the white color, and the color of the white light may be converted into one of the red color, the green color, and the blue color by the main color filter 521.

Also, in FIG. 6A, a structure wherein a color conversion medium is not stacked on the first main light-emitting element 310 was illustrated, but the disclosure is not limited thereto, and a color conversion medium may be stacked on the first main light-emitting element 310 as in FIG. 5. For example, the corresponding color conversion medium 511 may be stacked on each of the main light-emitting elements 310, 320, 330, and after the auxiliary color conversion medium 512 that converts a light emitted from the auxiliary light-emitting element 400 into a light of the white color is stacked on the upper side of the auxiliary light-emitting element 400, it may be found out that the first main light-emitting element 310 is defective. In this case, on the upper side of the first main light-emitting element 310, the black matrix 523 may be arranged, and on the upper side of the auxiliary color conversion medium 512, the auxiliary color filter 522 that selectively makes only a light of the first color corresponding to the first main light-emitting element 310 pass through may be arranged.

Referring to FIG. 6B, not only on the auxiliary light-emitting element 400 but also on the main light-emitting elements 310, 320, 330, the color conversion media 511a, 511b, 511c that convert lights emitted from each light-emitting element into lights of the white color may respectively be stacked.

For example, after the same color conversion media (e.g.: the color conversion media 511a, 511b, 511c and the auxiliary color conversion medium 512) are stacked on all of the main light-emitting elements 310, 320, 330 and the auxiliary light-emitting element 400, it may be found out that the first main light-emitting element 310 is defective. In this case, on the upper side of the first main light-emitting element 310, the black matrix 523 may be arranged, and on the upper side of the auxiliary color conversion medium 512, the auxiliary color filter 522 that selectively makes only a light of the first color corresponding to the first main light-emitting element 310 pass through may be arranged.

For example, according to the manufacturing process of the display panel and the time point when the defect of the light-emitting elements was found, the structures of the color conversion media and the color filter layer 520 may be changed variously.

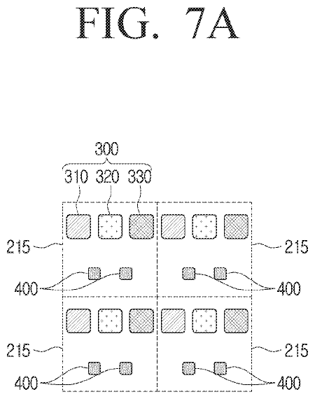

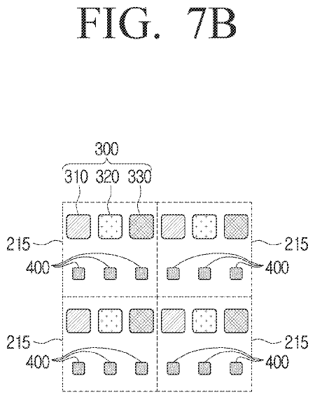

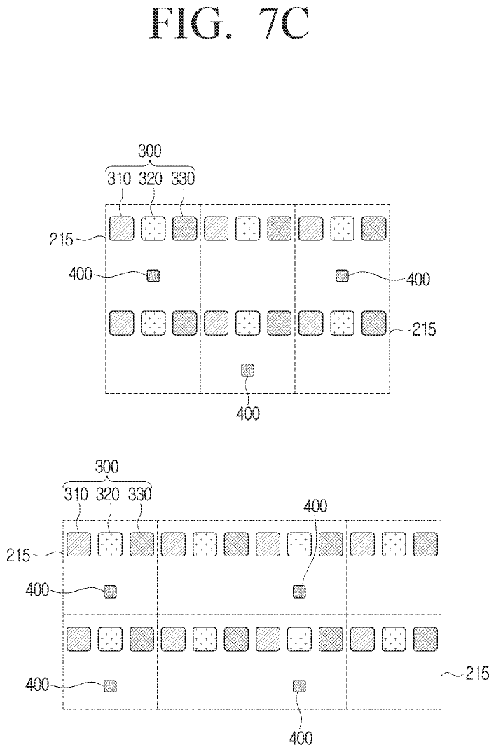

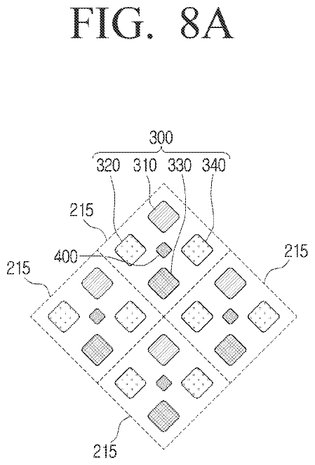

FIGS. 7A, 7B and 7C are diagrams illustrating an example pixel structure of a display panel according to various embodiments. Referring to FIG. 7A to 7C, the number of the auxiliary light-emitting elements 400 arranged in each pixel area 215 may be different.

For example, referring to FIG. 7A, two auxiliary light-emitting elements 400 may be arranged for each pixel area 215. Also, referring to FIG. 7B, three auxiliary light-emitting elements 400 may be arranged for each pixel area 215. In addition, referring to FIG. 7C, one auxiliary light-emitting element 400 may be arranged for two pixel areas 215.

For example, as in the structure on the upper side of FIG. 7C, the auxiliary light-emitting elements 400 may be arranged in a zig-zag form as the matrices of the pixel areas 215 change every time the columns of the pixel areas 215 in a lattice form change. Alternatively, as in the structure on the lower side of FIG. 7C, the auxiliary light-emitting elements 400 may be arranged only in the pixel areas 215 in one column among two neighboring columns of the pixel areas 215 in a lattice form.

Also, some of the plurality of pixel areas 215 may have the structure on the upper side of FIG. 7C, and some others may have the structure on the lower side of FIG. 7C. However, the structures in FIG. 7C illustrated only example structures wherein one auxiliary light-emitting element 400 is arranged for two pixel areas 215, and the arrangement of the auxiliary light-emitting elements 400 is not limited thereto.

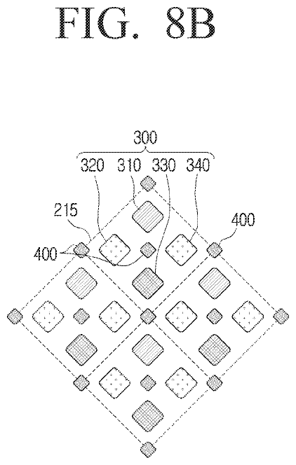

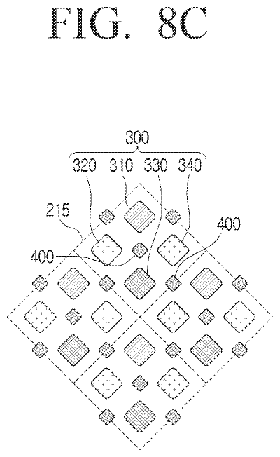

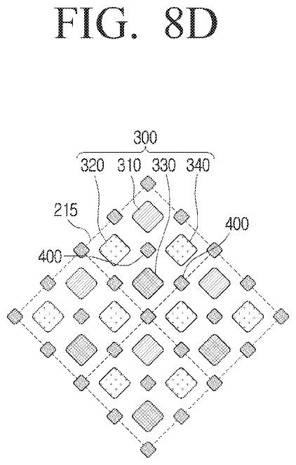

FIGS. 8A, 8B, 8C and 8D are diagrams illustrating example pentile matrix pixel structures of a display panel according to various embodiments.

Referring to FIGS. 8A to 8D, the plurality of main light-emitting elements 300 and the auxiliary light-emitting element 400 may be arranged in a pentile matrix structure. For example, the plurality of main light-emitting elements 300 may be arranged in an RGBG pentile matrix structure within one pixel area 215, and the auxiliary light-emitting element 400 may be arranged in a pentile matrix structure in the plurality of pixel areas 215.

According to an embodiment, the plurality of main light-emitting elements 300 may include the first main light-emitting element 310, the second main light-emitting element 320, the third main light-emitting element 330, and the fourth main light-emitting element 340. The first to fourth main light-emitting elements 310, 320, 330, 340 may respectively correspond to one color among the red color, the green color, and the blue color.

For example, the first main light-emitting element 310 may correspond to the red color, the second and the fourth main light-emitting elements 320, 340 may correspond to the green color, and the third main light-emitting element 330 may correspond to the blue color. Lights emitted by each of the first to fourth main light-emitting elements 310, 320, 330, 340 may be converted into lights of corresponding colors of each of them by the color conversion layer 500.

For example, referring to FIG. 8A, the auxiliary light-emitting element 400 may be arranged to be surrounded by the four main light-emitting elements 300, but is not limited thereto. Also, the auxiliary light-emitting element 400 may be arranged as a plurality of auxiliary light-emitting elements for each pixel area 215.

For example, referring to FIG. 8B, two auxiliary light-emitting elements 400 may be arranged for each pixel area 215. Also, referring to FIG. 8C, three auxiliary light-emitting elements 400 may be arranged for each pixel area 215. In addition, referring to FIG. 8D, four auxiliary light-emitting elements 400 may be arranged for each pixel area 215.

Referring to the structure in FIG. 8A, one auxiliary light-emitting element 400 may be arranged in one pixel area 215. Also, referring to the structure in FIG. 8B, five auxiliary light-emitting elements 400 in total may be arranged in one pixel area 215. In addition, referring to the structure in FIG. 8C, five auxiliary light-emitting elements 400 in total may be arranged in one pixel area 215. Further, referring to the structure in FIG. 8D, nine auxiliary light-emitting elements 400 in total may be arranged in one pixel area 215.

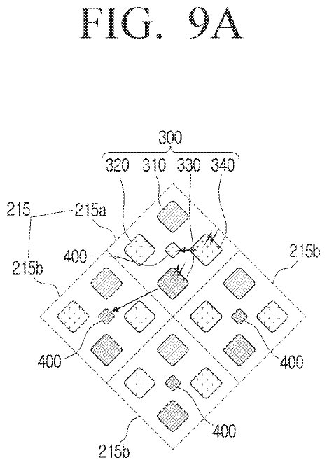

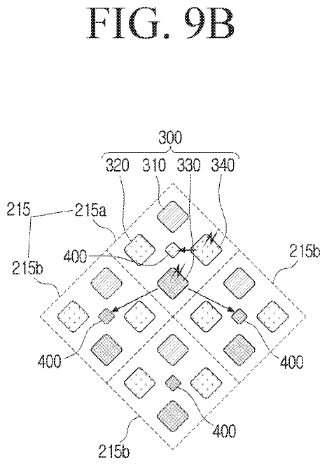

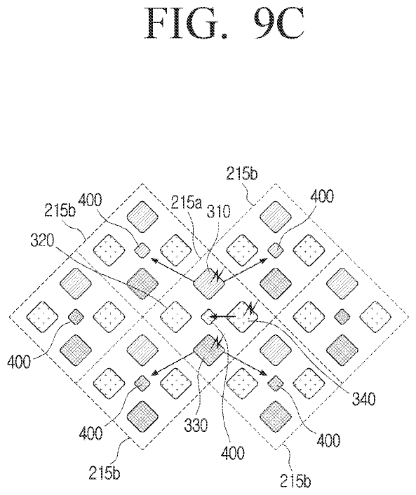

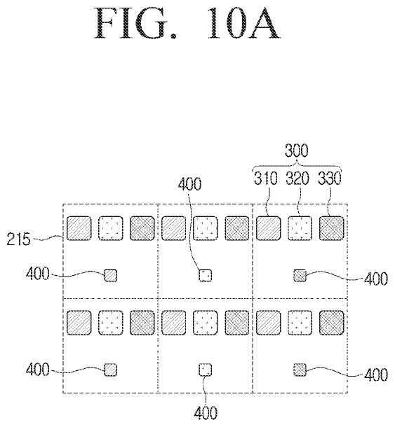

FIGS. 9A, 9B and 9C are diagrams illustrating examples wherein a plurality of main light-emitting elements are defective in one pixel area according to various embodiments

Referring to FIGS. 9A to 9C, the plurality of pixel areas 215 may include a first pixel area 215a and a plurality of second pixel areas 215b. The first pixel area 215a may be a n area wherein defective main light-emitting elements 300 are arranged, and the plurality of second pixel areas 215b may be areas adjacent to the first pixel area 215a. The plurality of second d pixel areas 215b may be arranged to surround the first pixel area 215a.

According to an embodiment, in the first pixel area 215a, two defective main light-emitting elements 300 may be arranged. That is, two main light-emitting elements 300 among the first to fourth main light-emitting elements 310, 320, 330, 340 may be defective. FIG. 9A and FIG. 9B illustrated cases wherein the third main light-emitting element 330 and the fourth main light-emitting element 340 are defective, but the disclosure is not limited thereto.

According to an embodiment, the color conversion layer 500 may be formed such that a light emitted from the auxiliary light-emitting element 400 in the first pixel area 215a has the first color corresponding to the first main light-emitting element 310 which is defective in the first pixel area 215a. Also, the color conversion layer 500 may be formed such that a light emitted from the auxiliary light-emitting element 400 in at least one second pixel area 215b among the plurality of second pixel areas 215b has the second color corresponding to the second main light-emitting element 320 which is defective in the first pixel area 215a.

Referring to FIG. 9A and FIG. 9B, the third main light-emitting element 330 and the fourth main light-emitting element 340 among the four main light-emitting elements 400 arranged in the first pixel area 215a may be defective. For example, in case the fourth main light-emitting element 340 corresponds to the green color, a light emitted from the auxiliary light-emitting element 400 in the first pixel area 215a may be converted into a light of the green color by the color conversion layer 500.

Also, in case the third main light-emitting element 330 corresponds to the blue color, a light emitted from the auxiliary light-emitting element 400 in one pixel area 215b among the plurality of second pixel areas 215b may be converted into a light of the blue color by the color conversion layer 500.

In addition, referring to FIG. 9B, in case the third main light-emitting element 330 corresponds to the blue color, lights emitted from the auxiliary light-emitting elements 400 in two second pixel areas 215b among the plurality of second pixel areas 215b may be converted into lights of the blue color by the color conversion layer 500.

For example, in case a plurality of main light-emitting elements 300 (e.g.: the third main light-emitting element 330, the fourth main light-emitting element 340) are defective in the first pixel area 215a, the roles of some of the defective main light-emitting elements 300 (e.g.: the third main light-emitting element 330, the fourth main light-emitting element 340) may be replaced by the auxiliary light-emitting element 400 in an adjacent pixel area 215b.

Referring to FIG. 9C, three main light-emitting elements 300 among the four main light-emitting elements 300 arranged in the first pixel area 215a may be defective. For example, the first light-emitting element 310, the third main light-emitting element 330, and the fourth main light-emitting element 340 may be defective, but the disclosure is not limited thereto.

For example, in case the first light-emitting element 310 corresponds to the red color, lights emitted from the auxiliary light-emitting elements 400 in two second pixel areas 215b among the plurality of second pixel areas 215b may be converted into lights of the red color by the color conversion layer 500.

Also, in case the third light-emitting element 330 corresponds to the blue color, lights emitted from the auxiliary light-emitting elements 400 in two second pixel areas 215b among the plurality of second pixel areas 215b may be converted into lights of the blue color by the color conversion layer 500.

In addition, in case the fourth light-emitting element 340 corresponds to the green color, a light emitted from the auxiliary light-emitting element 400 in the first pixel area 215a may be converted into a light of the green color by the color conversion layer 500.

Accordingly, in case a plurality of main light-emitting elements 300 in one pixel area 215a are defective, the plurality of pixel areas 215 may be driven normally with the help of an adjacent pixel area 215b.

For example, in case a plurality of main light-emitting elements 300 (e.g.: the first main light-emitting element 310, the third main light-emitting element 330, the fourth main light-emitting element 340) in one first pixel area 215a are defective, the roles of some of the defective main light-emitting elements 300 (e.g.: the third main light-emitting element 330, the fourth main light-emitting element 340) may be replaced by the auxiliary light-emitting element 400 in the adjacent pixel area 215b.

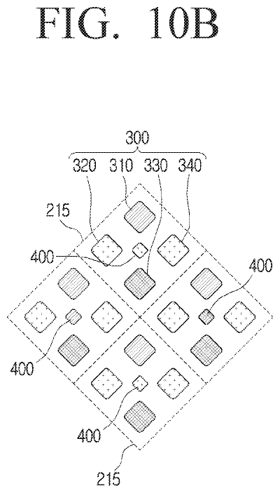

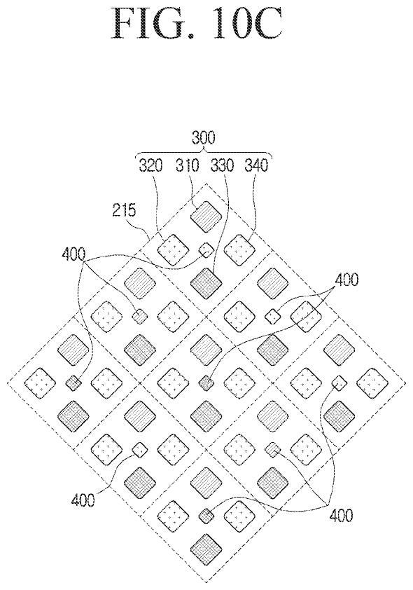

FIGS. 10A, 10B and 10C are diagrams illustrating in lights of which colors lights emitted from auxiliary light-emitting elements in normal pixel areas are converted according to various embodiments.

Referring to FIGS. 10A to 10C, the plurality of pixel areas 215 may include a defective pixel area (e.g.: the pixel area 215a in FIG. 9A to FIG. 9C) wherein at least one main light-emitting element 300 among the plurality of main light-emitting elements 300 is defective, and a normal pixel area wherein all of the plurality of main light-emitting elements 300 are not defective. For example, lights emitted from the auxiliary light-emitting elements 400 respectively arranged in a plurality of normal pixel areas may be formed to pass through the color conversion layer 500 and have colors in a predetermined ratio.

For example, referring to FIG. 10A, the plurality of main light-emitting elements may respectively correspond to the red color, the green color, and the blue color in a ratio of 1:1:1. For example, lights emitted from the auxiliary light-emitting elements 400 respectively arranged in the plurality of normal pixel areas may be formed to pass through the color conversion layer 500 and have the red color, the green color, and the blue color in a ratio of 1:1:1.

Also, referring to FIG. 10B, the plurality of main light-emitting elements 300 may respectively correspond to the red color, the green color, and the blue color in a ratio of 1:2:1. For example, lights emitted from the auxiliary light-emitting elements 400 respectively arranged in the plurality of normal pixel areas may be formed to pass through the color conversion layer 500 and have the red color, the green color, and the blue color in a ratio of 1:2:1.

In addition, referring to FIG. 10C, the plurality of main light-emitting elements 300 may respectively correspond to the red color, the green color, and the blue color in a ratio of 1:2:1. For example, the first main light-emitting element 310 may correspond to the red color, the second and fourth main light-emitting elements 320, 340 may correspond to the green color, and the third main light-emitting element 330 may correspond to the blue color. Here, lights emitted from the auxiliary light-emitting elements 400 respectively arranged in the plurality of normal pixel areas may be formed to pass through the color conversion layer 500 and have the red color, the green color, and the blue color in a ratio of 1:2:1.

For example, among the nine auxiliary light-emitting elements 400 in total that are respectively arranged in the nine pixel areas 215 by one each, four auxiliary light-emitting elements 400 may correspond to the green color, two auxiliary light-emitting elements 400 may correspond to the red color, and two auxiliary light-emitting elements 400 may correspond to the blue color. The auxiliary light-emitting element 400 arranged in the pixel area 215 located in the center may not emit a light, or may be covered by the black matrix 523.

As another example, among the nine auxiliary light-emitting elements 400 in total that are respectively arranged in the nine pixel areas 215 by one each, four auxiliary light-emitting elements 400 may correspond to the green color, three auxiliary light-emitting elements 400 may correspond to the red color, and two auxiliary light-emitting elements 400 may correspond to the blue color. For example, compared to the structure of the red color, the green color, and the blue color in a ratio of 1:2:1, the auxiliary light-emitting element 400 arranged in the pixel area 215 located in the center may correspond to the red color.

Accordingly, in case the main light-emitting elements 300 in the pixel areas 215 are not defective, the auxiliary light-emitting elements 400 may form an additional pixel structure.

Also, the color conversion layer 500 may be formed such that lights emitted from the auxiliary light-emitting elements 400 in the normal pixel areas pass through the color conversion layer 500 and have one color among the red color, the green color, and the blue color.

For example, the color conversion layer 500 may be formed such that lights emitted from the auxiliary light-emitting elements 400 in the normal pixel areas pass through the color conversion layer 500 and have the green color. Accordingly, the lights emitted from the auxiliary light-emitting elements 400 are converted into lights of the green color which is sensitive for human vision, and thus the auxiliary light-emitting elements 400 may be driven and controlled to emit green lights when necessary.

For example, the color conversion layer 500 may be formed such that lights emitted from the auxiliary light-emitting elements 400 in the normal pixel areas pass through the color conversion layer 500 and have the red color which is the luminance limit color. Accordingly, the lights emitted from the auxiliary light-emitting elements 400 may assist with the main light-emitting elements 300 and increase the entire luminance.

Also, the color conversion layer 500 may be formed such that lights emitted from the auxiliary light-emitting elements 400 in the normal pixel areas pass through the color conversion layer 500 and are converted into ultraviolet rays or infrared rays. Accordingly, the auxiliary light-emitting elements 400 may be used as a UV sensor or an IR sensor.

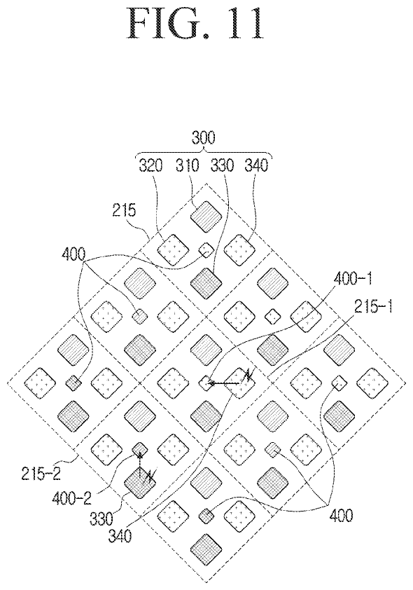

FIG. 11 is a diagram illustrating in lights of which colors lights emitted from auxiliary light-emitting elements in each pixel area are converted in case normal pixel areas and defective pixel areas are mixed according to various embodiments. Referring to FIG. 11, four main light-emitting elements 300 and one auxiliary light-emitting element 400 may be arranged for one pixel area 215.

According to an embodiment, the plurality of main light-emitting elements 300 may include the first main light-emitting element 310, the second main light-emitting element 320, the third main light-emitting element 330, and the fourth main light-emitting element 340. The first to fourth main light-emitting elements 310, 320, 330, 340 may respectively correspond to one color among the red color, the green color, and the blue color.

For example, the first main light-emitting element 310 may correspond to the red color, the second and fourth main light-emitting elements 320, 340 may correspond to the green color, and the third main light-emitting element 330 may correspond to the blue color. Lights emitted from each of the first to fourth main light-emitting elements 310, 320, 330, 340 may be converted into lights of corresponding colors of each of them by the color conversion layer 500. That is, a light emitted from one pixel area 215 may pass through the color conversion layer 500 and have the red color, the green color, and the blue color in a ratio of 1:2:1.

For example, among the nine pixel areas 215, the first pixel area 215-1 and the second pixel area 215-2 may be defective pixel areas wherein main light-emitting elements 300 which are defective are arranged, and the remaining seven pixel areas 215 may be normal pixel areas wherein main light-emitting elements 300 which are all normal are arranged.

For example, the fourth main light-emitting element 340 corresponding to the green color of the first pixel area 215-1 may be defective, and the third main light-emitting element 330 corresponding to the blue color of the second pixel area 215-2 may be defective. Accordingly, the auxiliary light-emitting element 400-1 of the first pixel area 215-1 may correspond to the green color, and the auxiliary light-emitting element 400-2 of the second pixel area 215-2 may correspond to the blue color.

Hereinafter, it will be described in greater detail how the corresponding colors of the auxiliary light-emitting elements 400 arranged in the remaining seven normal pixel areas are determined.

According to an embodiment, among the normal main light-emitting elements 300 arranged in the nine pixel areas 215, nine first main light-emitting elements 310 corresponding to the red color may be arranged, seventeen second and fourth main light-emitting elements 320, 340 corresponding to the green color may be arranged as one of the eighteen elements is defective, and eight third main light-emitting elements 330 corresponding to the blue color may be arranged as one of the nine elements is defective.

According to an embodiment, the ratio of the luminance of the main light-emitting elements 300 and the luminance of the auxiliary light-emitting elements 400 may be assumed as 1:K. Among the auxiliary light-emitting elements 400 arranged in the seven normal pixel areas, auxiliary light-emitting elements 400 in an a number may correspond to the red color, auxiliary light-emitting elements 400 in a b number may correspond to the green color, and auxiliary light-emitting elements 400 in a c number may correspond to the blue color.

$$a + b + c = 7 \qquad [ Formula 1 ]$$

Here, a may be the number of the auxiliary light-emitting elements 400 corresponding to the red color in the normal pixel areas, b may be the number of the auxiliary light-emitting elements 400 corresponding to the green color in the normal pixel areas, and c may be the number of the auxiliary light-emitting elements 400 corresponding to the blue color in the normal pixel areas.

According to an embodiment, the luminance ratio of each color of all main light-emitting elements 300 and the auxiliary light-emitting elements 400 arranged in the nine pixel areas 215 may be set to be the same as the luminance ratio of each color in the normal pixel areas (e.g., the luminance ratio of the red color, the green color, and the blue color is 1:2:1). This may be expressed as a formula as follows.

$$R : G : B = 9 + a \cdot K : 17 + ( 1 + b ) \cdot K : 8 + ( 1 + c ) \cdot K = 12 : 1 \qquad [ Formula 2 ]$$

Here, R may be the luminance of a red light, G may be the luminance of a green light, and B may be the luminance of a blue light.

According to a predetermined K value, integers a, b, and c satisfying the aforementioned [Formula 1] and [Formula 2] to the maximum may be calculated, and the corresponding colors of the auxiliary light-emitting elements 400 arranged in the seven normal pixel areas may be determined. For example, a may be determined as 2, b may be determined as 3, and c may be determined as 2.

Accordingly, even if some main light-emitting elements 300 are defective, they may be corrected by the auxiliary light-emitting elements 400, and accordingly, the target luminance ratio can be maintained, and at the same time, the luminance can rise on the whole.

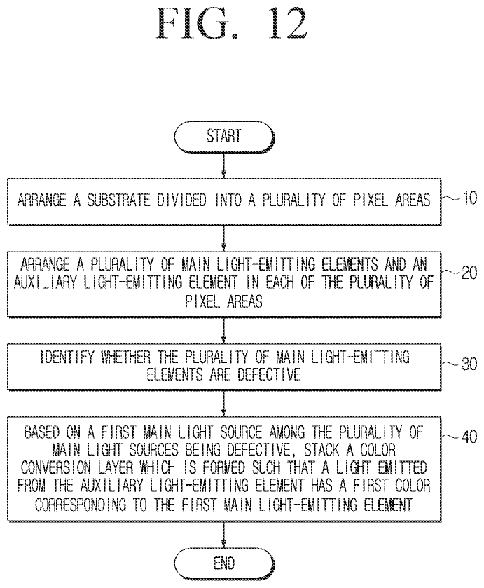

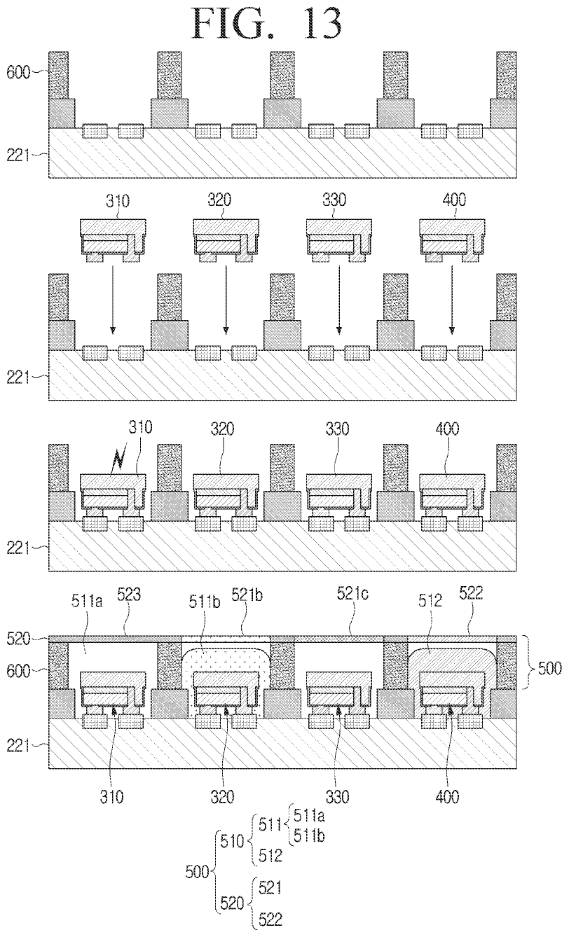

FIG. 12 and FIG. 13 include a flowchart and diagrams illustrating an example method for manufacturing a display panel according to various embodiments.

Referring to FIG. 12 and FIG. 13, a method for manufacturing a display panel according to an embodiment of the disclosure may include the steps of arranging a substrate 221 which is divided into a plurality of pixel areas (10), arranging a plurality of main light-emitting elements 310, 320, 330 and an auxiliary light-emitting element 400 in each of the plurality of pixel areas (20), identifying whether the plurality of main light-emitting elements 310, 320, 330 are defective (30), and based on a first main light-emitting element 310 among the plurality of main light-emitting elements 310, 320, 330 being defective, stacking a color conversion layer 500 which is formed such that a light emitted from the auxiliary light-emitting element 400 has a first color corresponding to the first main light-emitting element 310 (40).

According to an embodiment, the plurality of main light-emitting elements 310, 320, 330 and the auxiliary light-emitting element 400 may be arranged on the substrate 221 on which a barrier 600 dividing the sub-pixel areas is provided. The plurality of main light-emitting elements 300 and the auxiliary light-emitting element 400 may be blue micro light-emitting diodes (LEDs) emitting blue lights.

According to an embodiment, the plurality of main light-emitting elements 300 may include the first main light-emitting diode 310, the second main light-emitting diode 320, and the third main light-emitting diode 330. The first to third main light-emitting diodes 310, 320, 330 may respectively correspond to one color among the red color, the green color, and the blue color, and lights emitted by each of them may be converted into lights of corresponding colors of each of them by the color conversion layer 500. The plurality of main light-emitting elements 310, 320, 330 may respectively correspond to the red color, the green color, and the blue color.

The plurality of main light-emitting elements 310, 320, 330 may be driven, and it may be identified whether the light-emitting elements are defective. In case the first main light-emitting diode 310 is defective, the color conversion layer 500 that is formed such that a light emitted from the auxiliary light-emitting element 400 has the red color corresponding to the first main light-emitting element 310 may be stacked.

According to an embodiment, the color conversion layer 500 may include a color conversion medium 510 and a color filter layer 520. The color conversion medium 510 may include a main color conversion medium 511 stacked on the main light-emitting elements 300 and an auxiliary color conversion medium 512 stacked on the auxiliary light-emitting element 400.

According to an embodiment, the main color conversion medium 511 may include a second main color conversion medium 511b stacked on the second main light-emitting element 320. The second main color conversion medium 511b may include a green phosphor that is excited by a light emitted from the second main light-emitting element 320 and emits a light of a green wavelength band.

According to an embodiment, the auxiliary color conversion medium 512 may convert a light emitted from the auxiliary light-emitting element 400 into a light of the first color (e.g., red) corresponding to the first main light-emitting element 310 which is defective among the plurality of main light-emitting elements 300.

Accordingly, even in case the main light-emitting elements 300 in a specific pixel area are defective, the auxiliary light-emitting element 400 passes through the auxiliary color conversion medium 512 and is converted into a light of a corresponding color of the main light-emitting elements 300 which are defective, and thus the pixel may be driven normally.

According to an embodiment, the color filter layer 520 may include the plurality of main light-emitting elements 300, color filters 521, 522 which are arranged on the upper side of the auxiliary light-emitting element 400, and are of different colors, and a black matrix 523. For example, the color filter layer 520 may include a main color filter 521 respectively arranged on the upper side of the plurality of main light-emitting elements 300, an auxiliary color filter 522 arranged on the upper side of the auxiliary light-emitting element 400, and the black matrix 520 arranged to surround the plurality of color filters.

According to an embodiment, the main color filter 521 may include a second main color filter 521b and a third main color filter 521c. The second main color filter 521b may be arranged on the upper side of the second main light-emitting element 320, and the third main color filter 521c may be arranged on the upper side of the third main light-emitting element 330.

According to an embodiment, the second main color filter 521b may be a filter including color pixels expressing a second color (e.g., green). For example, the second main color filter 521b may be a filter that includes a polarizing member, and selectively makes a light of a wavelength corresponding to the second color pass through, and absorbs a light of another wavelength.

Likewise, the third main color filter 521c may be a filter including color pixels expressing a third color (e.g., blue). For example, the third main color filter 521c may be a filter that includes a polarizing member, and selectively makes a light of a wavelength corresponding to the third color pass through, and absorbs a light of another wavelength.

According to an embodiment, the auxiliary color filter 522 may be stacked on the auxiliary color conversion medium 512, and selectively make only a light of the first color (e.g., red) corresponding to the first main light-emitting element 310 which is defective among the plurality of main light-emitting elements 300 pass through. Accordingly, color reproducibility in sub-pixels corresponding to the auxiliary light-emitting element 400 can be improved.

According to an embodiment, the black matrix 523 may be arranged on the upper side of the first main light-emitting element 310 which is defective. That is, on the upper side of the first main light-emitting element 310 which is defective, a color conversion medium may not be stacked, but the black matrix 523 may be arranged. Accordingly, in case the first main light-emitting element 310 which is defective emits a light unintentionally, the light may be absorbed by the black matrix 523.

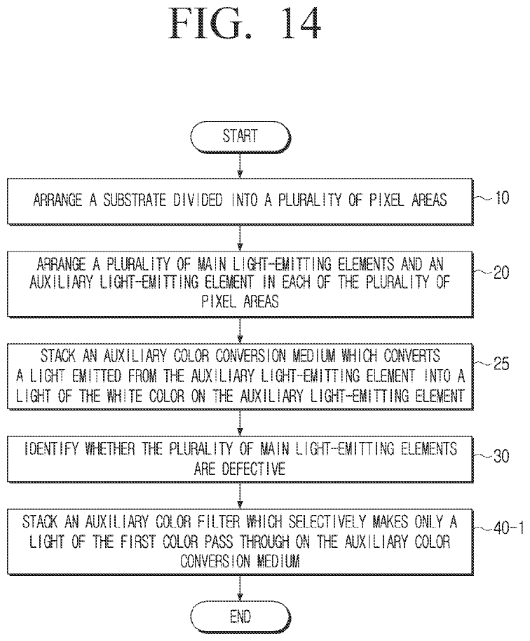

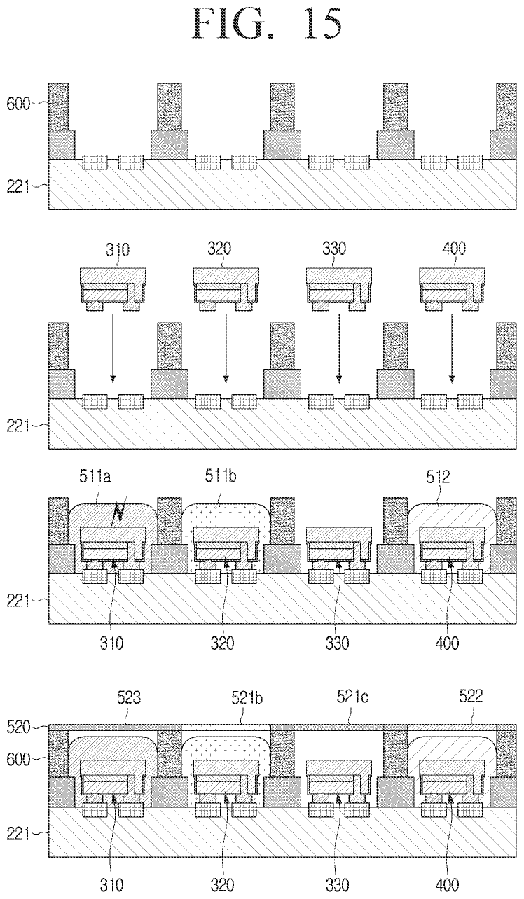

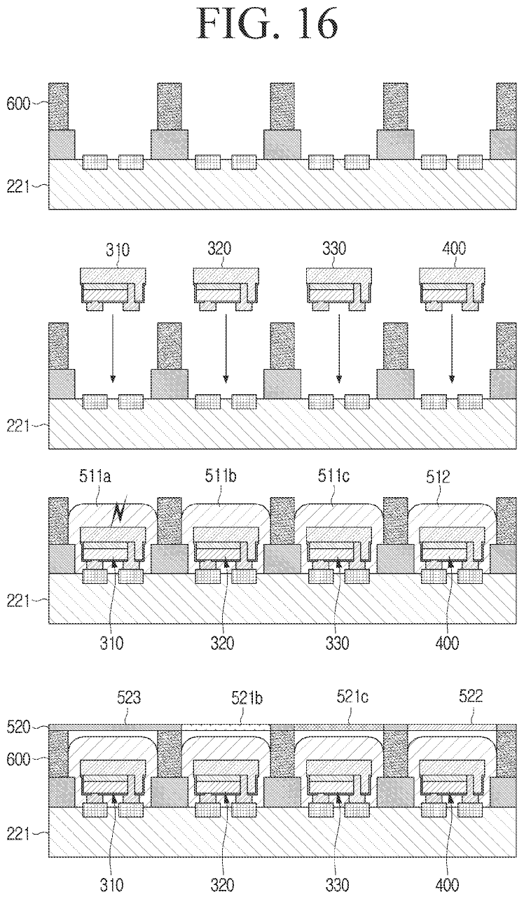

FIGS. 14, 15 and 16 include a flowchart and diagrams illustrating an example method for manufacturing a display panel according to various embodiments.

Referring to FIG. 14 to FIG. 16, a method for manufacturing a display module according to an embodiment of the disclosure may further include, after the operation 20 of arranging light-emitting elements in FIG. 12, an operation 25 of stacking the auxiliary color conversion medium 512 that converts a light emitted from the auxiliary light-emitting element 400 into a light of the white color on the auxiliary light-emitting element 400

In other words, according to the sequential diagram illustrated in FIG. 14, after stacking the color conversion media on the main light-emitting elements 310, 320, 330 and the auxiliary light-emitting element 400, it may be identified whether the main light-emitting elements 310, 320, 330 are defective.

As illustrated in FIG. 15, the main color conversion medium 511 stacked on the main light-emitting elements 300 may include a first main color conversion media 511a and a second color conversion media 511b, The first main color conversion media 511a may include a red phosphor, and the second main color conversion media 511b may include a green phosphor.

Alternatively, as illustrated in FIG. 16, the main color conversion media 511 may include the first to third main color conversion media 511a, 511b, 511c that are respectively stacked on the first to third main light-emitting elements 310, 320, 330, and convert lights emitted from the light-emitting elements into lights of the white color.

Before it is identified which one of the first to third main light-emitting elements 310, 320, 330 is defective, on the auxiliary light-emitting element 400, the auxiliary color conversion medium 512 that converts a light emitted from the auxiliary light-emitting element into a light of the white color may be stacked.

It may then be identified whether the main light-emitting elements 310, 320, 330 are defective, and the type of the auxiliary color filter 522 may be determined. Specifically, if it is identified that the first main light-emitting diode 310 is defective, the type of the auxiliary color filter 522 may be determined such that a light emitted from the auxiliary light-emitting element 400 passes through the auxiliary color filter 422 and is changed to the first color.

That is, the operation 40 of stacking the color conversion layer in FIG. 12 may be an operation 40-1 of stacking the auxiliary color filter 522 that selectively makes only a light of the first color (e.g., red) pass through in FIG. 14 on the auxiliary color conversion medium 512.

Accordingly, even in case the first main light-emitting diode 310 is defective, the auxiliary light-emitting element 400 passes through the auxiliary color filter 522 and is converted into a light of the corresponding color of the first main light-emitting diode 310 which is defective, and thus the pixel can be driven normally.

The display panel according to various example embodiments of the disclosure may include: a substrate divided into a plurality of pixel areas, a plurality of main-light emitting diodes and an auxiliary light-emitting element respectively mounted on the plurality of pixel areas, and a color conversion layer stacked on the plurality of main-light emitting diodes and the auxiliary light-emitting element. According to various example embodiments, the color conversion layer may be configured such that a light emitted from the auxiliary light-emitting element passes through the color conversion layer and has the first color corresponding to a defective first main light-emitting diode among the plurality of main light-emitting diodes.

According to various example embodiments, the color conversion layer may include an auxiliary color conversion medium stacked on the auxiliary light-emitting element and configured to convert a light emitted from the auxiliary light-emitting element into a light of the first color.

According to various example embodiments, the color conversion layer may include an auxiliary color filter stacked on the auxiliary color conversion medium configured to selectively make only a light of the first color pass through.

According to various example embodiments, the color conversion layer may include an auxiliary color conversion medium stacked on the auxiliary light-emitting element and configured to convert a light emitted from the auxiliary light-emitting element into a light of the white color, and an auxiliary color filter stacked on the auxiliary color conversion medium configured to selectively make only a light of the first color pass through.

According to various example embodiments, the color conversion layer may include a color filter layer arranged on the upper side of the plurality of main light-emitting elements and the auxiliary light-emitting element, and includes color filters of different colors and the black matrix. Also, according to various example embodiments, the black matrix may be arranged on the upper side of the first main light-emitting element.

According to various example embodiments, the plurality of main light-emitting elements and the auxiliary light-emitting element may be arranged in a pentile matrix structure.

According to various example embodiments, the auxiliary light-emitting elements may be arranged as a plurality of auxiliary light-emitting elements for each pixel area.

According to various example embodiments, the plurality of pixel areas may include a first pixel area and a plurality of second pixel areas adjacent to the first pixel area. Also, according to various example embodiments, the color conversion layer may be configured such that a light emitted from the auxiliary light-emitting element in the first pixel area has the first color corresponding to the first defective main light-emitting element in the first pixel area, and may be configured such that a light emitted from the auxiliary light-emitting element in at least one second pixel area among the plurality of second pixel areas has the second color corresponding to the second defective main light-emitting element in the first pixel area.

According to various example embodiments, the plurality of main light-emitting elements may respectively correspond to the red color, the green color, and the blue color in a specified ratio. Also, according to various example embodiments, the color conversion layer may be configured such that lights emitted from the auxiliary light-emitting elements of the plurality of pixel areas pass through the color conversion layer and have colors in the specified ratio.

According to various example embodiments, the specified ratio may be 1:1:1 or 1:2:1.

According to various example embodiments, the plurality of pixel areas=may include a defective pixel area wherein at least one main light-emitting element among the plurality of main light-emitting elements is defective, and a normal pixel area wherein all of the plurality of main light-emitting elements are not defective. Also, according to various example embodiments, the color conversion layer may be configured such that lights emitted from the auxiliary light-emitting elements in the normal pixel areas pass through the color conversion layer and have one color among the red color, the green color, and the blue color.

According to various example embodiments, the plurality of pixel areas may include a defective pixel area wherein at least one main light-emitting element among the plurality of main light-emitting elements is defective, and a normal pixel area wherein all of the plurality of main light-emitting elements are not defective. Also, according to various example embodiments, the color conversion layer may be configured such that lights emitted from the auxiliary light-emitting elements in the normal pixel areas pass through the color conversion layer and are converted into ultraviolet rays or infrared rays.

According to various example embodiments, the plurality of main light-emitting elements and the auxiliary light-emitting element may be blue micro LEDs configured to emit blue light.

A method for manufacturing the display panel according to various example embodiments of the disclosure may include: arranging a substrate divided into a plurality of pixel areas, arranging a plurality of main light-emitting elements and an auxiliary light-emitting element in each of the plurality of pixel areas, identifying whether the plurality of main light-emitting elements are defective, and based on a first main light-emitting element among the plurality of main light-emitting elements being defective, stacking a color conversion layer configured such that a light emitted from the auxiliary light-emitting element has a first color corresponding to the first main light-emitting element.

According to various example embodiments, the color conversion layer may include an auxiliary color conversion medium stacked on the auxiliary light-emitting element and configured to convert a light emitted from the auxiliary light-emitting element into a light of the first color.

According to various example embodiments, the color conversion layer may include an auxiliary color filter stacked on the auxiliary color conversion medium and configured to selectively make only a light of the first color pass through.

The method for manufacturing the display module according to various example embodiments may further include, after the mounting operation, an operation of stacking the auxiliary color conversion medium configured to convert a light emitted from the auxiliary light-emitting element into a light of the white color on the auxiliary light-emitting element. According to various example embodiments, the operation of stacking the color conversion layer may include an operation of stacking an auxiliary color filter configured to selectively make only a light of the first color pass through on the auxiliary color conversion medium.

The electronic device according to various example embodiments of the disclosure may include: a display panel including a substrate divided into a plurality of pixel areas, a plurality of main light-emitting elements and an auxiliary light-emitting element which are mounted in each of the plurality of pixel areas, a color conversion layer stacked on the plurality of main light-emitting elements and the auxiliary light-emitting element, and a driving circuit configured to generate a driving signal of the plurality of main light-emitting elements and the auxiliary light-emitting element, and at least one processor, comprising processing circuitry, individually and/or collectively configured to: control the driving circuit to generate a driving signal for controlling light emission of the plurality of main light-emitting elements and the auxiliary light-emitting element. According to various example embodiments, the color conversion layer may be configured such that a light emitted from the auxiliary light-emitting element passes through the color conversion layer and has a first color corresponding to a first defective main light-emitting element among the plurality of main light-emitting elements.

According to various example embodiments, the color conversion layer may include an auxiliary color conversion medium stacked on the auxiliary light-emitting element and configured to convert a light emitted from the auxiliary light-emitting element into a light of the first color.

According to various example embodiments, the color conversion layer may include an auxiliary color conversion medium stacked on the auxiliary light-emitting element and configured to convert a light emitted from the auxiliary light-emitting element into a light of the white color, and an auxiliary color filter stacked on the auxiliary color conversion medium and configured to selectively make only a light of the first color pass through.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A display panel comprising:
a substrate divided into a plurality of pixel areas;
a plurality of main light-emitting elements and an auxiliary light-emitting element mounted in each of the plurality of pixel areas; and
a color conversion layer stacked on the plurality of main light-emitting elements and the auxiliary light-emitting element,
wherein the color conversion layer is configured such that a light emitted from the auxiliary light-emitting element passes through the color conversion layer and has a first color corresponding to a defective first main light-emitting element among the plurality of main light-emitting elements.

2. The display panel of claim 1,
wherein the color conversion layer comprises:
an auxiliary color conversion medium stacked on the auxiliary light-emitting element and configured to convert the light emitted from the auxiliary light-emitting element into the light of the first color.

3. The display panel of claim 2,
wherein the color conversion layer comprises:
an auxiliary color filter stacked on the auxiliary color conversion medium and configured to selectively make only the light of the first color pass through.

4. The display panel of claim 1,
wherein the color conversion layer comprises:
an auxiliary color conversion medium stacked on the auxiliary light-emitting element and configured to convert the light emitted from the auxiliary light-emitting element into a light of a white color; and
an auxiliary color filter stacked on the auxiliary color conversion medium and configured to selectively make only the light of the first color pass through.

5. The display panel of claim 1,
wherein the color conversion layer comprises:
a color filter layer arranged on an upper side of the plurality of main light-emitting elements and the auxiliary light-emitting element, and includes color filters of different colors and a black matrix, and
the black matrix is arranged on an upper side of the first main light-emitting element.

6. The display panel of claim 1,
wherein the plurality of main light-emitting elements and the auxiliary light-emitting element are arranged in a pentile matrix structure.

7. The display panel of claim 1,
wherein the auxiliary light-emitting element is arranged as a plurality of auxiliary light-emitting elements for each of the pixel areas.

8. The display panel of claim 1,
wherein the plurality of pixel areas comprise a first pixel area and a plurality of second pixel areas adjacent to the first pixel area, and
the color conversion layer is configured such that a light emitted from an auxiliary light-emitting element of the first pixel area has the first color corresponding to the defective first main light-emitting element of the first pixel area, and
is configured such that a light emitted from an auxiliary light-emitting element of at least one second pixel area among the plurality of second pixel areas has a second color corresponding to a defective second main light-emitting element of the first pixel area.

9. The display panel of claim 1,
wherein the plurality of main light-emitting elements respectively correspond to a red color, a green color, and a blue color in a specified ratio,
the color conversion layer is configured such that lights emitted from auxiliary light-emitting elements of the plurality of pixel areas pass through the color conversion layer and have colors in the specified ratio, wherein
the specified ratio is 1:1:1 or 1:2:1.

10. The display panel of claim 1,
wherein the plurality of pixel areas comprise:
a defective pixel area wherein at least one main light-emitting element among the plurality of main light-emitting elements is defective; and
a normal pixel area wherein all of the plurality of main light-emitting elements are not defective, and
the color conversion layer is configured such that light emitted from the auxiliary light-emitting elements of the normal pixel area pass through the color conversion layer and have one color among a red color, a green color, and a blue color.

11. The display panel of claim 1,
wherein the plurality of pixel areas comprise:
a defective pixel area wherein at least one main light-emitting element among the plurality of main light-emitting elements is defective; and
a normal pixel area wherein all of the plurality of main light-emitting elements are not defective, and
the color conversion layer is configured such that light emitted from the auxiliary light-emitting elements of the normal pixel area pass through the color conversion layer and are converted into infrared rays or ultraviolet rays.

12. The display panel of claim 1,
wherein the plurality of main light-emitting elements and the auxiliary light-emitting element are blue micro LEDs configured to emit a blue light.

13. A method of manufacturing a display panel, the method comprising:
arranging a substrate divided into a plurality of pixel areas;
mounting a plurality of main light-emitting elements and an auxiliary light-emitting element in each of the plurality of pixel areas;
identifying whether the plurality of main light-emitting elements are defective; and
based on a first main light-emitting element among the plurality of main light-emitting elements being defective, stacking a color conversion layer configured such that a light emitted from the auxiliary light-emitting element has a first color corresponding to the first main light-emitting element.

14. The method for manufacturing a display panel of claim 13,
wherein the color conversion layer comprises:
an auxiliary color conversion medium stacked on the auxiliary light-emitting element and configured to convert the light emitted from the auxiliary light-emitting element into the light of the first color, and
an auxiliary color filter stacked on the auxiliary color conversion medium and configured to selectively make only the light of the first color pass through.

15. The method for manufacturing a display panel of claim 13, further comprising:
after the mounting operation, stacking an auxiliary color conversion medium configured to convert the light emitted from the auxiliary light-emitting element into a light of a white color on the auxiliary light-emitting element, and
wherein the stacking the color conversion layer comprises:
stacking an auxiliary color filter configured to selectively make only the light of the first color pass through on the auxiliary color conversion medium.
